(19) United States
(12) Patent Application Publication
(10) Pub. No.: US 2006/0246727 A1
(43) Pub. Date: Nov. 2, 2006

(54) Integrated dual damascene clean apparatus and process

(75) Inventors: Ching-Hua Hsieh, Hsinchu (TW); Chao-Chen Chen, Hsin-Chu (TW); Shau-Lin Shue, Hsinchu (TW); Hun-Jan Tao, HsinChu (TW); Mong-Song Liang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/115,693

(22) Filed: Apr. 27, 2005

(51) Int. Cl. H01L 21/311; H01L 21/306; C23C 16/00

(52) U.S. Cl. 438/694; 156/345.32; 118/719

(57) ABSTRACT

An integrated apparatus comprises a plasma etching station, a wet cleaning station, a de-gassing station, a thin film deposition station, and a wafer transfer mechanism to automatically index wafers between the stations in a predetermined processing order.

### BACKGROUND

Methods of forming reliable and efficient interconnections are important in the art of integrated circuit manufacturing. Interconnects between active and passive devices are typically formed by the application of conductive films. For example, an aluminum film may be sputtered onto an integrated circuit substrate. This film is then patterned by a lithography and etching sequence to create aluminum lines connecting various points in the circuit. This approach, wherein the conductive film is first deposited and then is patterned by lithography and etching, has been the dominant method of interconnect formation until recently.

In more recent practice, a technique called damascene or dual damascene has become popular. In a damascene technique, a dielectric layer is deposited and then patterned to form channels, or trenches, for planned conductive lines. In addition, through vias are formed for planned vias to connect different levels of conductive lines. If both through vias and trenches are formed in the same dielectric layer or in a stack of dielectric layers, then the technique is called dual damascene.

The dual damascene method is typically used for interconnect systems comprising copper. Copper is an attractive choice for metal interconnects in the integrated circuit. Copper has a significantly lower resistivity than aluminum and is therefore a useful material for very high-speed circuits. However, unlike aluminum, it is very difficult to reliably etch copper. The dual damascene process allows very precise copper vias and lines to be formed without a precise copper etching process. However, there are challenges related to the ease of oxidation and other characteristics of copper to be overcome.

A further consideration of the copper dual damascene manufacturing process is Q-time. Q-time is the waiting time between sequential processes in the manufacturing line. In a typical integrated circuit manufacturing operation, also called a fab, many thousands of product wafers may be in the work in progress (WIP) of the fab at any given time. These product wafers are typically at a variety of points in the standard product manufacturing sequence, or flow. In addition, the fab comprises a finite number of manufacturing tools, such as plasma etching machines or physical vapor deposition machines. A given manufacturing tool might be used multiple times during the complete fabrication sequence for a product wafer. Further, this tool might be used for fabricating different families or types of wafers. As a result, the manufacturing management of a modern integrated circuit facility is a very complex problem where production flow bears more resemblance to a spider web than to Henry Ford's sleek assembly line.

The combination of complex product fabrication flows, multiple uses and recipes for tools, and constantly changing customer schedules causes the typical IC fab to carry a large level of WIP and to exhibit a relatively slow cycle time when compared to more straightforward assembly lines. As a result of large WIP and slow cycle time, it is not unusually for product wafers to have significant Q-times between process steps. These Q-times are typically measured in hours if not days. In many cases, longs Q-times between process steps cause no problems other than the economic costs of slow throughput. However, it is found that extensive Q-time can have negative effects on the quality of the finish product. This has been especially demonstrated for the above-described dual damascene process.

### BRIEF DESCRIPTION OF THE DRAWINGS

Aspects of the present disclosure are best understood from the following detailed description when studied with the accompanying figures. In the drawings, various features may not be drawn to scale.

FIGS. 1 through 10 are cross-sectional views of a wafer showing the formation of a dual damascene interconnect using an embodiment of an integrated dual damascene clean apparatus or cluster tool.

FIG. 11 is a block diagram of an embodiments of an integrated dual damascene clean apparatus or cluster tool.

FIG. 12 is a block diagram of an embodiments of an integrated dual damascene clean apparatus or cluster tool in a wafer fab.

FIG. 13 is a flowchart of an embodiment of a process flow for using an integrated dual damascene clean apparatus or cluster tool to manufacture a damascene interconnect.

### DETAILED DESCRIPTION

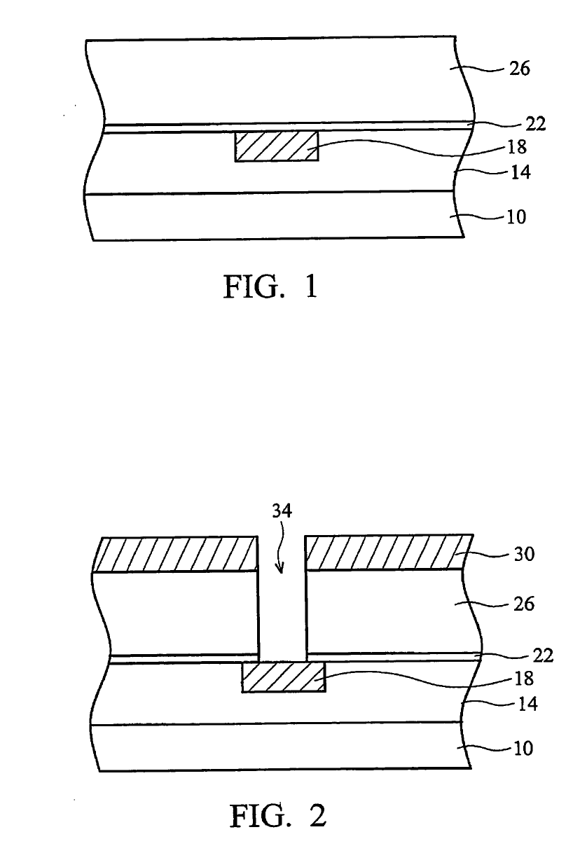

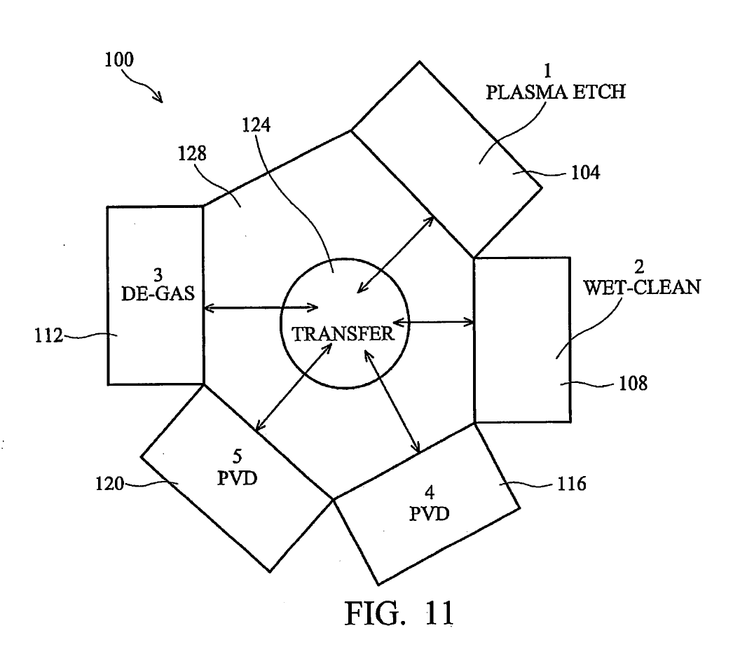

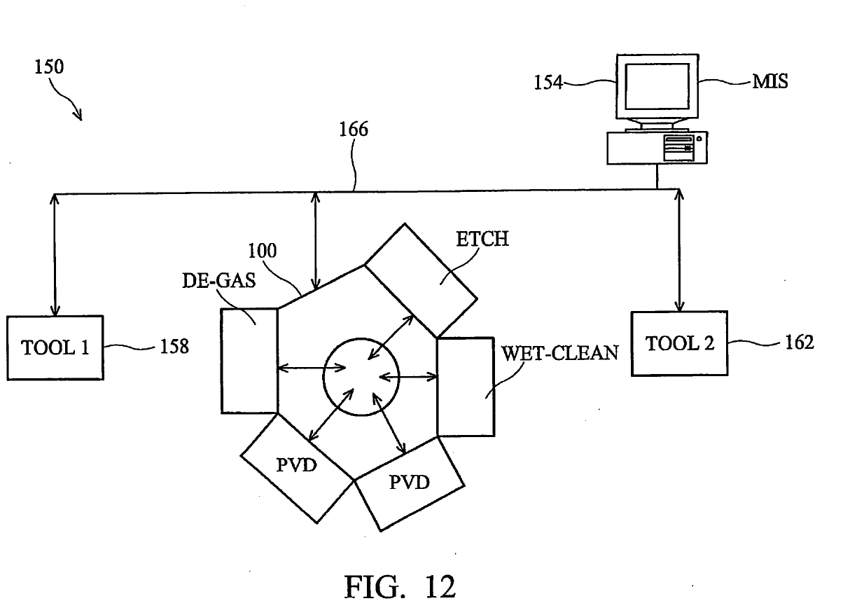

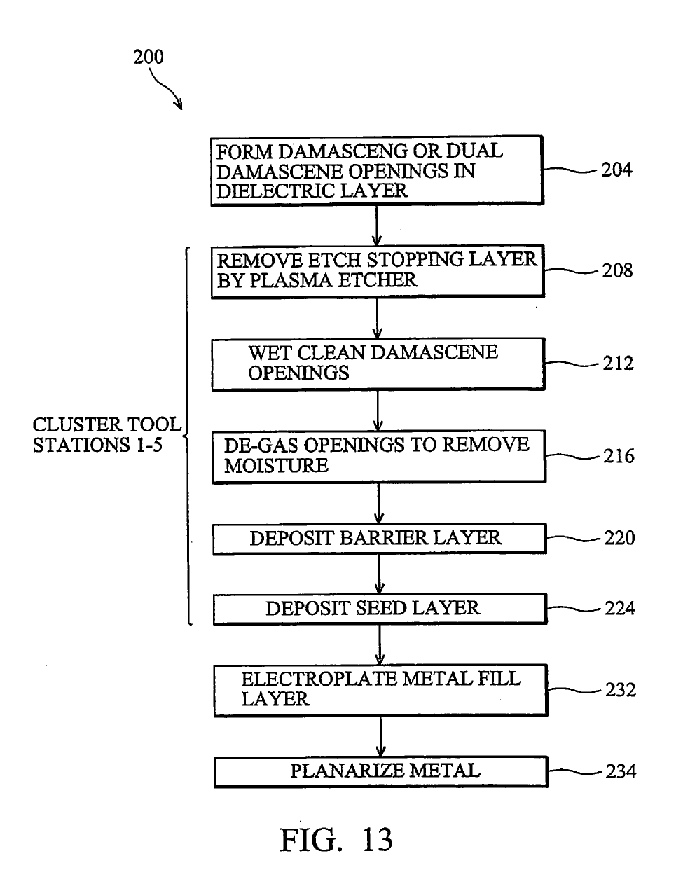

FIGS. 1 through 10 are cross-sectional views of a wafer showing the formation of a dual damascene interconnect using an embodiment of an integrated dual damascene clean apparatus or cluster tool. FIG. 11 is a block diagram of an embodiments of an integrated dual damascene clean apparatus or cluster tool. FIG. 12 is a block diagram of an embodiments of an integrated dual damascene clean apparatus or cluster tool in a wafer fab. FIG. 13 is a flowchart of an embodiment of a process flow for using an integrated dual damascene clean apparatus or cluster tool to manufacture a damascene interconnect. In the discussion, the basic features of the cluster tool of FIGS. 11 and 12 will be described first. Then the application of this cluster tool to the formation of the dual damascene structure in the manufacture of the integrated circuit device is discussed and illustrated in FIGS. 1 through 10 and in FIG. 13.

Referring now to FIG. 11, a novel, cluster tool 100 is illustrated. Several important features of the present invention are shown and discussed below. The cluster tool 100 comprises several processing stations 104, 108, 112, 116, and 120. These stations are selected and configured to provide an integrated approach to performing the critical dual damascene steps of (1) etch stopping layer removal, (2) wet cleaning, and (3) barrier/seed deposition. The cluster tool 100 comprises, first, a plasma etch station (station 1) 104 for performing the etch stopping layer removal. Second, a wet cleaning station (station 2) 108 is provided for cleaning the via and the top surface of the underlying metal line after the removal of the etch stopping layer but before deposition of barrier/seed layers. Third, a degassing station (station 3) 112 is included to rapidly remove any moisture left from the wet cleaning operation prior to the deposition of barrier/seed layers. Fourth, a first physical vapor deposition (PVD) station (station 4) 116 is provided for depositing a barrier layer. Fifth, a second PVD station (station 5) 120 is included for depositing a seed layer. The above-described stations are preferably mounted or configured in a single mainframe 128. This mainframe 128 provides a semi-permanent arrangement of tools dedicated to the dual damascene cleaning process. The mainframe 128 may be a frame or housing that ties or holds the multiple stations together. A wafer transfer mechanism 124 is included to provide automated wafer movement between the stations. The configuration of the stations need not strictly comply with that shown in FIG. 11.

In the preferred operation, a production lot of wafers is loaded into the cluster tool 100 at the transfer mechanism 124. The various stations 1-5 of the cluster tool may be configured to process the same number of wafers at a time.

Referring to FIG. 12, the cluster tool 100 is shown within the larger context of a wafer fab 150. As described above, the wafer fab 150 comprises a large number of manufacturing tools as depicted by TOOL1 158 and TOOL2 162. A manufacturing information system (MIS) 154 is used to track WIP, to determine the selection of the next product lot to be processed at its next process step, to coordinate the movement of material through the fab, and to perform other functions. In a typical configuration, the MIS 154 works using a move in/move out principle. As product lots are processed through the overall process flow for that product type, the lots are moved into a tool to carry out a specific operation, such as the wet cleaning operation, prior to performing the wet clean process. Then, after the wet clean process is performed, the lot is moved out of that tool. The move in/move out is performed by an operator interaction with the MIS system or is performed by an automated equipment interaction with the MIS system. The automated equipment interactions are performed over equipment-to-MIS communication lines 166.

One advantage of the present invention is that the cluster tool 100 can be treated by the MIS system as a single tool for purposes of moving the product lot. That is, the product lot is moved into the cluster tool, both physically and within the MIS database, to begin the process steps. Next, the product lot is run through the entire process sequence, from etch stopping layer removal through seed deposition, without a significant inter-process Q-time. When the entire dual damascene etch-clean-deposit sequence of the cluster tool 100 is completed, then the product is physically moved out. The cluster tool reduces the complexity of MIS design that would be needed to both effectively manage the product flow and to keep Q-times very short.

Another advantage of the cluster tool is that the trench baking process of the prior art can be eliminated. In the prior art, a trench bake is performed following the wet cleaning of the dual damascene opening and prior to the barrier/seed layer deposition. This trench bake process is included so that the product wafers can withstand a significant Q-time of up to about eight hours between the wet cleaning operation and the barrier/seed layer deposition. In the novel cluster tool of the present invention, the Q-times between process steps are measured in seconds or minutes. Therefore, it is not necessary to add a long baking process to extend the shelf life of the wet cleaned openings. Rather, a short de-gassing process (station 3) 112 is used instead of the baking operation. The de-gassing process is used to drive off any moisture remaining after the wet cleaning operation (station 2) 108 prior to barrier/seed deposition (stations 4 and 5) 116 and 120.

It may be seen from FIG. 11 that two stations 116 and 120 are provided for PVD processing. Alternatively, one of the stations may perform chemical vapor deposition (CVD), atomic layer deposition (ALD), or another type of deposition process. If, for example, a barrier layer is used that is deposited by CVD, then station 116 may be a CVD tool. If the barrier layer is deposited by atomic layer deposition, then station 116 may be an ALD tool. The seed layer used in copper dual damascene may also be deposited by PVD, CVD, or ALD.

The preferred use of the present invention is illustrated in FIGS. 1-10 which show a first preferred embodiment of the invention as applied to the manufacture of a dual damascene interconnect of an integrated circuit device. The device is shown in cross sectional representations in FIGS. 1-10. In addition, a partial manufacturing flow 200 for the dual damascene process is shown in FIG. 13. In the description below, the manufacturing flow of FIG. 13 and the cross sectional views of FIGS. 1-10 are references and further described with respect to the cluster tool 100 of FIG. 11.

Referring now to FIG. 13, the partial manufacturing flow 200 begins with step 204 where damascene and dual damascene openings are formed in the dielectric layer of the integrated circuit. Referring now to FIG. 1, the integrated circuit device is shown in simplified cross-section. A substrate 10 is provided. The substrate 10 preferably comprises a semiconductor material and, more preferably, comprises silicon. Since the metal interconnect levels are formed at the end of the processing sequence, typically a plurality of active and passive devices will have been formed in and on the substrate at this point in the fabrication process. A first dielectric layer 14 has been formed overlying the substrate 10. The first dielectric layer 14 comprises an insulating material, such as silicon oxide, that can electrically isolate the first conductive lines 18 from the underlying substrate 10 and features. The first conductive lines 18 comprise a patterned conductive film, such as aluminum or copper. The first conductive lines 18 may be connected to underlying features in or near the substrate using via openings, not shown.

As first steps in forming the dual damascene interconnection level, an etch stop layer 22 is formed overlying the first dielectric layer 14 and the first conductive lines 18. Next, a second dielectric layer 26 is formed overlying the etch stop layer 22. The etch stop layer 22 comprises a material that has a significantly slower etching rate than the second dielectric layer 26 in the etching process used to formed via openings in the second dielectric layer 26. For example, if the second dielectric layer 26 comprises a silicon oxide-based material, then a material other than silicon oxide may be advantageously used for the etch stop layer 22. The etch stop layer 22 preferably comprises silicon nitride, silicon carbide, silicon oxynitride, or silicon oxycarbide.

Referring now to FIG. 2, via openings 34 are etched through the second dielectric layer 26. These openings 34 may be defined using, for example, a lithography and etch sequence. In the example case, a resist layer 30 is first deposited, or coated, overlying the second dielectric layer 26. The resist layer 30 is then exposed to actinic light through a photo mask, not shown, to cause a part of the resist layer 30 polymer structure to be cross-linked while a part is not cross-linked. A developer is then applied to remove either the cross-linked or the non-cross linked part of the resist 30 and to thereby transfer a positive or negative image of the photo mask to the remaining resist 30. The second dielectric layer 26 is then etched through using, for example, a plasma or reactive ion etching process. The patterned resist layer 30 acts as a mask to guide the etching process. Following the via opening 34 etch, the remaining resist layer 30 is removed using, for example, a plasma stripping or ashing process. The resulting openings 34 are called via openings 34 because they extend down to the underlying first conductive lines 18 with only the etch stop layer 22 therebetween. The etch stop layer 22 protects the first conductive lines 18 from damage during the etching process while allowing the process to completely remove the second dielectric layer 26 from the via openings 34.

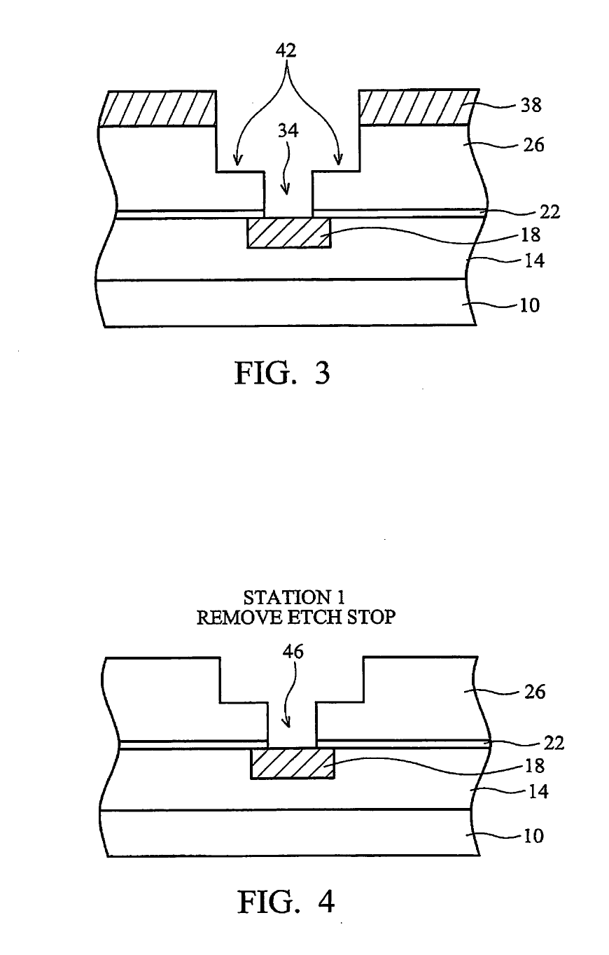

Referring now to FIG. 3, in a similar fashion, the trench openings 42 are formed in the second dielectric layer 26. Again, a second patterned resist layer 38 may be formed overlying the second dielectric layer 26. In this case, the trench openings 42 are somewhat wider than the via openings 34 and, most importantly, the trench openings 42 do not extend through the second dielectric layer 26. The trench opening 42 depth can be controlled by either timing the anisotropic etching process (such as a plasma or reactive ion etch), or by forming a second etch stop layer (not shown) in the second dielectric layer 26 at the desired depth. In either case, the etch stop layer 22 again protects the underlying first conductive lines 18 from damage during the trench etching process. This completes the initial formation of the dual damascene openings as described in FIG. 13, step 204.

Steps 208, 212, 216, 220, and 224 of FIG. 13 are all performed in the cluster tool 100 in stations 1 through 5. Referring again to FIG. 11, the product wafer, or wafer lot, is loaded into the transfer mechanism 124 of the cluster tool 100. The product wafer, or group of wafers, is then indexed into the plasma etch station (station 1) 104 by the transfer mechanism 124. The etch stop layer 22 is removed by the plasma etcher 104 in step 208 of FIG. 13. Referring now to FIG. 4, the top surfaces 46 of the first conductive lines 18 are exposed by the removal of the etch stop layer 22. Again, the dissimilarity of the etch stop layer 22 and of the second dielectric layer 26 allows for a selective etching of one layer, this time of the etch stopping layer 22, while leaving the other layer intact.

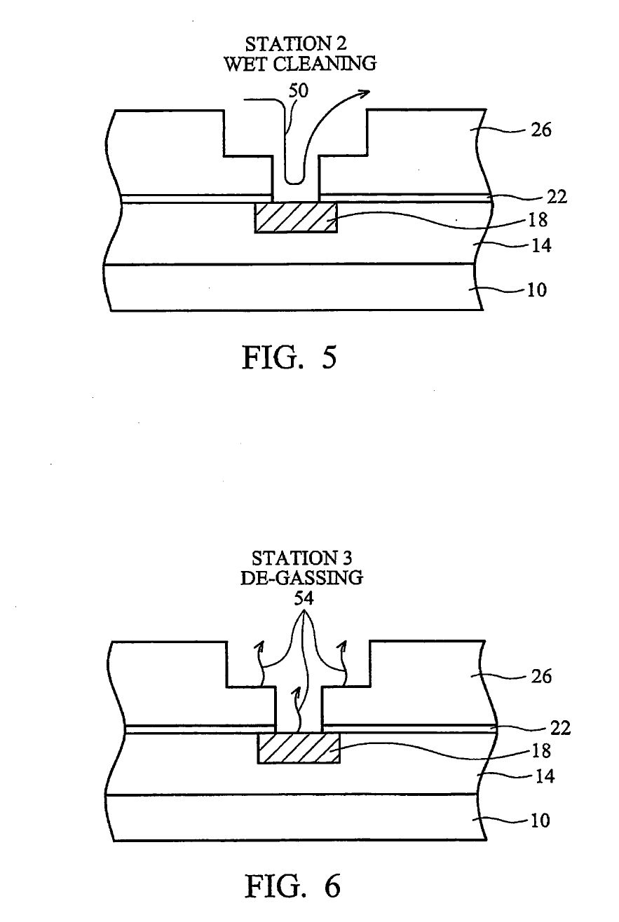

Referring again to FIG. 11, the product wafer, or wafer group, is then indexed from the plasma etcher 104 to the wet cleaning station (station 2) 108. The damascene openings are then wet cleaned in step 212 of FIG. 13. Referring now to FIG. 5, the wet cleaning solution 50 physically and chemically treats the dual damascene openings and the exposed first conductive lines 18. In particular, the wet cleaning solution 50 removes any residue from the etching processes. In addition, the wet cleaning solution 50 may reduce oxides from the exposed surfaces of the first conductive lines 18.

Referring again to FIG. 11, the wafers, or wafer group, are now indexed from the wet cleaning station to the de-gassing station (station 3) 112. The de-gassing station 112 uses a combination of heat, air movement, and/or vacuum to remove moisture from the wafer surface prior to the barrier/seed layer deposition in step 216 of FIG. 13. Referring now to FIG. 6, the prior wet cleaning operation may leave some moisture 54, typically de-ionized water, on the surface of the wafers. Some moisture 54 is likely to be trapped in the dual damascene openings. The de-gassing station removes this moisture 54 by driving it off as vapor. However, unlike the prior art process, a long baking time is not required.

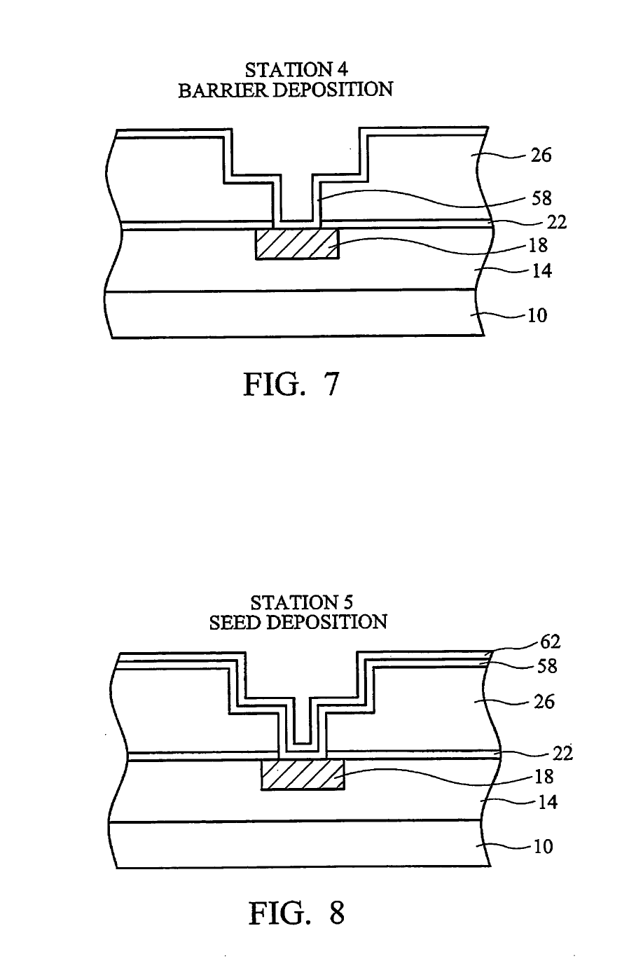

Referring again to FIG. 11, the wafers, or wafer group, are now indexed from the de-gassing station to the first deposition station (station 4) 116. In the first deposition station 116, a barrier layer is deposited to line the dual damascene openings in step 220 of FIG. 13. Referring now to FIG. 7, a thin barrier layer 58 is deposited. Preferably, this barrier layer 58 comprises a film, such as a metal nitride, that is both conductive and is a barrier to the diffusion of copper ions. For example, titanium nitride or tungsten nitrogen carbide, may be used as the barrier layer 58. This deposition may be performed using a PVD process. Hence, the first deposition station (station 4) 116 of the cluster tool comprises a PVD chamber as shown. The small Q-time between the wet cleaning and de-gassing stations 108 and 112 and the barrier deposition station 116 insures excellent reliability of the final interconnect structure.

Referring again to FIG. 11, the wafers, or wafer group, are now indexed from the first deposition station to the second deposition station (station 5) 120. In the second deposition station 120, a seed layer 62 (FIG. 8) is deposited overlying the barrier layer in step 224 of FIG. 13. Preferably, this seed layer 62 comprises a thin film of copper. For example, a film of copper of between about 100 Å and about 1,500 Å is deposited. As described above, this seed layer 62 assures that the subsequent plating process will form a good quality copper layer to fill the dual damascene openings. Preferably, this seed layer 62 deposition is performed using a physical vapor deposition process (PVD). Hence, the second deposition station (station 5) 120 of the cluster tool comprises a PVD chamber as shown. As an alternative, it is possible that the first deposition station 4 can be used for both barrier layer 58 and seed layer 62 deposition. In that case, the second PVD station 120 may be eliminated from the cluster tool 100.

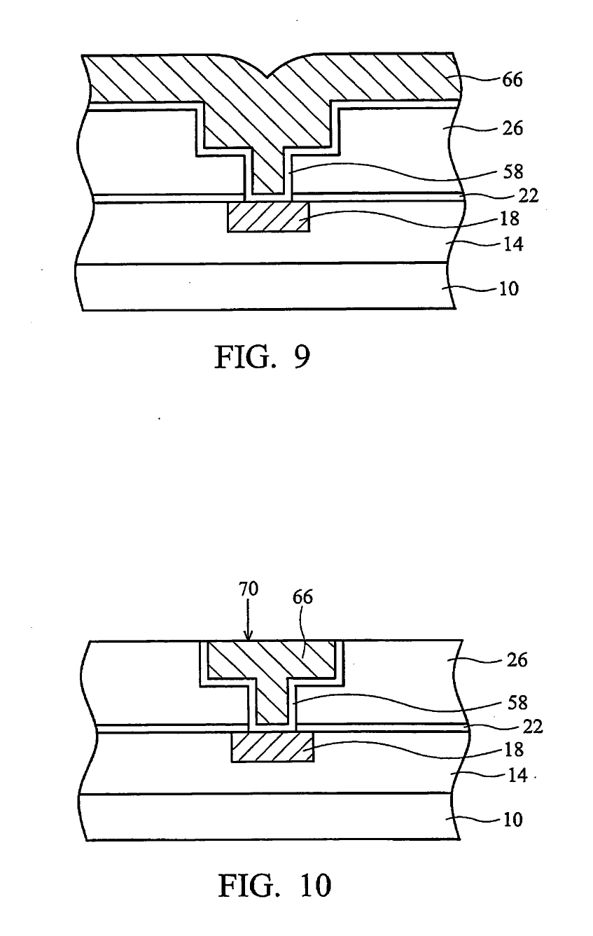

Following the deposition of the seed layer 62, the wafers, or wafer group, are now indexed from the second deposition station to the off loading point of the transfer mechanism 124 of the cluster tool 100. In subsequent processing, a plating process is used to fill the dual damascene openings with metal in step 232 and a planarization process is used to remove excess metal and to complete the definition of the interconnect lines and vias in step 234 of FIG. 13. Referring now to FIG. 9, a plating process is used to deposit a thick layer of metal 66 to fill the damascene openings. The plating process may comprise electroplating or electroless plating as is known in the art. Preferably, the plated metal 66 comprises copper. The seed layer 62 is consumed into the plated metal layer 66. Referring now to FIG. 10, the metal layer 66 is planarized. Preferably, a chemical mechanical polish (CMP) process is used. Alternatively, other planarization methods or downward etching methods may be used. As a result, the excess metal layer 66 is removed to thereby confine the metal 66 to the dual damascene trenches. The planarization process may also remove excess barrier layer 58 from the surface of the second dielectric layer 26.

The novel cluster tool apparatus and method of manufacture results in an improved dual damascene process. The new process eliminates excessive Q-times between critical cleaning and deposition steps to thereby improve reliability. The new process also eliminates a time-wasting trench baking process between wet cleaning and barrier/seed deposition processes.

While the invention has been particularly shown and described with reference to the preferred embodiments thereof, it will be understood by those skilled in the art that various changes in form and details may be made without departing from the spirit and scope of the invention.

What is claimed is:

1. An integrated circuit manufacturing apparatus comprising:
a plasma etching station;
a wet cleaning station;
a de-gassing station;
a thin film deposition station; and
a wafer transfer mechanism to automatically index wafers between the stations in a predetermined processing order.

2. The apparatus according to claim 1, wherein the plasma etching station is operable to selectively etch away an etch stop layer while leaving a damascene patterned dielectric layer.

3. The apparatus according to claim 1, wherein the wet cleaning station is operable to remove residue from process of the plasma etching station.

4. The apparatus according to claim 1, wherein the de-gassing station is operable to remove moisture from the wafers after processing in the wet cleaning station.

5. The apparatus according to claim 1, wherein the thin film deposition station is selected from the group consisting of a chemical vapor deposition chamber, a physical vapor deposition chamber, and an atomic layer deposition chamber.

6. The apparatus according to claim 1, wherein the thin film deposition station is operable to deposit a barrier layer without a trench baking process.

7. The apparatus according to claim 1, wherein the thin film deposition station is operable to sequentially deposit a barrier layer and an electroplating seed layer.

8. The apparatus according to claim 1, further comprising a second thin film deposition station.

9. The apparatus according to claim 1, further comprising a manufacturing information system coupled to and controlling the apparatus.

10. The apparatus according to claim 1, wherein all of the stations in the apparatus process the same number of the wafers during each cycle time.

11. The apparatus according to claim 1, wherein all of the stations are held together by a mainframe.

12. An integrated circuit manufacturing apparatus comprising:
a plasma etching station;
a wet cleaning station;
a de-gassing station wherein the de-gassing station is capable of removing moisture from the wafers after processing in the wet cleaning station;
a thin film deposition station;
a wafer transfer mechanism to automatically index wafers between the stations in a predetermined processing order; and
a manufacturing information system coupled to the integrated circuit manufacturing apparatus and controlling the apparatus as a single integrated tool.

13. The apparatus according to claim 12, wherein the plasma etching station is operable to selectively etch an etch stop layer while leaving a damascene patterned dielectric layer.

14. The apparatus according to claim 12, wherein the wet cleaning station is operable to remove residue from process of the plasma etching station.

15. The apparatus according to claim 12, wherein one of the thin film deposition stations is selected from a group consisting of a chemical vapor deposition chamber, an atomic layer deposition chamber, and a physical vapor deposition chamber.

16. The apparatus according to claim 12, wherein all of the stations in the apparatus process the same number of the wafers during each cycle time.

17. A method to form an interconnect structure in the manufacture an integrated circuit device comprising:
forming a conductive line overlying a substrate;
forming an etch stop layer overlying the conductive line;
forming a dielectric layer overlying the etch stop layer;
etching an opening through the dielectric and the etch stop layer;
wet cleaning the opening to remove residue from the conductive line;
de-gassing the conductive line and the dielectric layer to remove moisture;
depositing a barrier layer overlying the conductive line and lining the opening;
depositing a seed layer overlying the barrier layer without a trench baking step; and
plating a metal layer to fill the openings to complete the interconnect structure.

18. The method of claim 17, wherein the steps of etching through the etch stopping layer, wet cleaning the opening to remove residue from the conductive line, de-gassing the conductive lines and the dielectric layer to remove moisture, depositing a barrier layer overlying the conductive line and lining the opening, and depositing a seed layer overlying the barrier layer are performed in a cluster tool apparatus comprising:
a plasma etching station;
a wet cleaning station;
a de-gassing station wherein the de-gassing station is capable of removing moisture from the wafers after processing in the wet cleaning station;
a first thin film deposition station;
a second thin film deposition station; and
a wafer transfer mechanism to automatically index wafers between the stations in a predetermined processing order.

19. The method according to claim 17, wherein the etch stop layer is selected from the group consisting of silicon nitride, silicon carbide, silicon oxynitride, and silicon oxycarbide.

20. The method according to claim 18, wherein the apparatus is coupled to and is controlled by a manufacturing information system.

21. The method according to claim 18, wherein all of the stations in the apparatus process the same number of the wafers during each cycle time.
